(19) United States
(12) Patent Application Publication
(10) Pub. No.: US 2023/0217724 A1
(43) Pub. Date: Jul. 6, 2023

(54) DISPLAY DEVICE

(71) Applicant: LG Display Co., Ltd., Seoul (KR)

(72) Inventors: SeungSeok RYOO, Seoul (KR); Byeong-Seong SO, Seoul (KR)

(73) Assignee: LG Display Co., Ltd., Seoul (KR)

(21) Appl. No.: 17/987,623

(22) Filed: Nov. 15, 2022

(30) Foreign Application Priority Data
Dec. 30, 2021 (KR) 10-2021-0192133

(51) Int. Cl. H01L 27/32; H01L 51/52

(52) U.S. Cl. CPC H01L 27/3246; H01L 51/5284

(57) ABSTRACT

Discussed is a display device including a substrate, a circuit element on the substrate, a light emitting element electrically connected to the circuit element and including a first electrode, a light emitting layer, and a second electrode. A bank can define the emission area where the first electrode is exposed, and define the non-emission area where the bank is located, a taper pattern can be on the substrate and interposed between the circuit element and the bank at the non-emission area. The bank can include an incline extending from an edge of the emission area to a predetermined distance into the non-emission area, the incline of the bank defining a taper area, and the taper pattern can be adjacent to or overlap the taper area.

### CROSS-REFERENCE TO RELATED APPLICATION

This application claims priority to Korean Patent Application No. 10-2021-0192133, filed in the Republic of Korea on Dec. 30, 2021, the entire contents of which are hereby expressly incorporated by reference into the present application.

### BACKGROUND OF THE DISCLOSURE

### Field

Embodiments of the disclosure relate to a display device that prevents degradation of image quality due to reflection of light.

### Description of Related Art

Examples of display devices for displaying an image based on digital data include liquid crystal display (LCD) devices using liquid crystal, and organic light emitting display devices using organic light emitting diodes (OLEDs).

Among these example display devices, the organic light emitting displays use light emitting diodes and thus have fast responsiveness and various merits such as improved contrast ratio, luminous efficiency, brightness, and viewing angles. In this instance, the light emitting diode can be implemented with an inorganic material or an organic material.

The organic light emitting display includes a light emitting diode in subpixels arranged on the display panel and enables the light emitting diodes to emit light by controlling the current flowing to the light emitting diodes, thereby controlling the brightness represented by each subpixel while displaying an image.

Such a display device includes a plurality of subpixels on a substrate to display an image. The light emitting element disposed in each subpixel can be formed of an organic light emitting diode including a first electrode, a light emitting layer, and a second electrode.

In this instance, a bank pattern can be interposed between the first electrode and the light emitting layer to define each subpixel. The bank pattern has an opening exposing a portion of the first electrode. A light emitting layer is disposed on the first electrode exposed by the opening, and a second electrode is disposed on the light emitting layer and the bank pattern. Accordingly, the bank pattern defines each subpixel and serves to prevent a short circuit between the first electrode and the second electrode.

The bank pattern can include a taper area that contacts the edge of the first electrode and forms a constant slope. In this instance, when the taper area of the bank is formed at a low angle less than a reference slope, the incoming light is reflected at a predetermined angle on the taper area to the second electrode to spread the color and can cause a rainbow mura.

### SUMMARY OF THE DISCLOSURE

Accordingly, provided in the embodiments of the disclosure is a display device capable of enhancing image quality by forming the slope of the taper area to be larger than or equal to a reference value.

Embodiments of the disclosure can provide a display device having a structure capable of forming a slope of a taper area to be larger than or equal to a reference value while maintaining a sufficient thickness of the bank.

Embodiments of the disclosure can provide a display device having a structure capable of forming a slope of the taper area to be larger than or equal to a reference value by disposing a metal pattern at a lower portion of a layer overlapping the taper area.

Embodiments of the disclosure can provide a display device having a structure capable of forming a slope of the taper area to be larger than or equal to a reference value by disposing a taping spacer in the taper area.

Embodiments of the disclosure can provide a display device including a substrate, a circuit element disposed on the substrate, a light emitting element electrically connected to the circuit element and including a first electrode, a light emitting layer, and a second electrode, a bank disposed to form an emission area as a portion of an upper surface of the first electrode is exposed, at least one spacer disposed on the bank, and a taper control element disposed in at least a partial area overlapping a taper area of the bank to increase a slope of the taper area of the bank adjacent to the emission area.

According to embodiments of the disclosure, there can be provided a display device capable of enhancing image quality by forming the slope of the taper area to be larger than or equal to a reference value.

According to embodiments of the disclosure, there can be provided a display device having a structure capable of forming a slope of a taper area to be larger than or equal to a reference value while maintaining a sufficient thickness of the bank.

According to embodiments of the disclosure, there can be provided a display device having a structure capable of forming a slope of the taper area to be larger than or equal to a reference value by disposing a metal pattern at a lower portion of a layer overlapping the taper area.

According to embodiments of the disclosure, there can be provided a display device having a structure capable of forming a slope of the taper area to be larger than or equal to a reference value by disposing a taping spacer in the taper area.

According to embodiments of the disclosure, there can be provided a display device having a substrate including an emission area and a non-emission area; a circuit element on the substrate; a light emitting element electrically connected to the circuit element and including a first electrode, a light emitting layer, and a second electrode; a bank on the first electrode, and defining the emission area where the first electrode is exposed, and defining the non-emission area where the bank is located; a taper pattern on the substrate and interposed between the circuit element and the bank at the non-emission area, wherein the bank includes an incline extending from an edge of the emission area to a predetermined distance into the non-emission area, the incline of the bank defining a taper area, and wherein the taper pattern is adjacent to or overlaps the taper area.

According to embodiments of the disclosure, there can be provided a display device having a substrate including an emission area and a non-emission area; a circuit element on the substrate; a light emitting element electrically connected to the circuit element and including a first electrode, a light emitting layer, and a second electrode; a bank on the first electrode, and defining the emission area where the first electrode is exposed, and defining the non-emission area where the bank is located; and a taping spacer on the bank, wherein the bank includes an incline extending from an edge of the emission area to a predetermined distance into the non-emission area, the incline of the bank defining a taper area, and wherein the taping spacer is on the taper area of the bank and has a different slope from a slope of the incline of the bank.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view schematically illustrating a configuration of a display device according to embodiments of the disclosure;

FIG. 2 is a view exemplarily illustrating a configuration in which a plurality of subpixels and spacers are arranged in a display panel of a display device according to embodiments of the disclosure;

FIG. 3 is a cross-sectional view exemplarily illustrating a display panel according to embodiments of the disclosure;

FIG. 4 is a view exemplarily illustrating a cross section of an emission area and a non-emission area in a display panel of a display device;

FIG. 5 is a view exemplarily illustrating a cross section of an emission area and a non-emission area in a display device according to embodiments of the disclosure;

FIG. 6 is a plan view exemplarily illustrating an emission area where a metal pattern is disposed in a display device according to embodiments of the disclosure;

FIG. 7 is a view exemplarily illustrating an arrangement of subpixels and a metal pattern in a display device according to embodiments of the disclosure;

FIG. 8 is a plan view exemplarily illustrating an emission area where a metal pattern is disposed in a discontinuous structure in a display device according to embodiments of the disclosure;

FIG. 9 is a view exemplarily illustrating a cross section when a taping spacer is formed in a taper area of a bank in a display device according to embodiments of the disclosure;

FIG. 10 is a plan view exemplarily illustrating an emission area where a taping spacer is disposed in a display device according to embodiments of the disclosure;

FIG. 11 is a view exemplarily illustrating a process of adjusting the thickness of a taping spacer using a mask pattern in a display device according to embodiments of the disclosure; and

FIG. 12 is a plan view exemplarily illustrating a mask pattern for forming a taping spacer in a display device according to embodiments of the disclosure.

### DETAILED DESCRIPTION OF THE EMBODIMENTS

Hereinafter, embodiments of the disclosure will be described in detail with reference to example drawings. In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Hereinafter, embodiments of the disclosure will be described in detail with reference to the accompanying drawings.

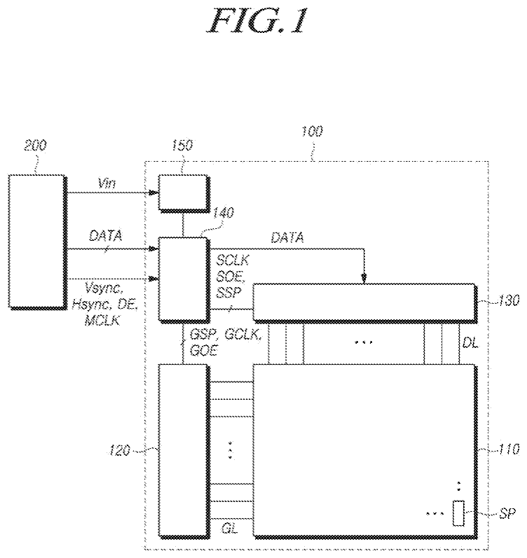

FIG. 1 is a view schematically illustrating a configuration of a display device according to various embodiments of the disclosure. All components of each display device according to all embodiments of the disclosure are operatively coupled and configured.

Referring to FIG. 1, a display device 100 according to embodiments of the disclosure can include a display panel 110 where a plurality of gate lines GL and data lines DL are connected, and a plurality of subpixels SP are arranged in a matrix form, a gate driving circuit 120 driving the plurality of gate lines GL, a data driving circuit 130 supplying a data voltage through the plurality of data lines DL, a timing controller 140 controlling the gate driving circuit 120 and the data driving circuit 130, and a power management circuit 150.

The display panel 110 displays an image based on a scan signal transferred from the gate driving circuit 120 through the plurality of gate lines GL and the data voltage transferred from the data driving circuit 130 through the plurality of data lines DL.

In the instance of a liquid crystal display, the display panel 110 can include a liquid crystal layer formed between two substrates and can be operated in any known mode, such as a twisted nematic (TN) mode, a vertical alignment (VA) mode, an in-plane switching (IPS) mode, or a fringe field switching (FFS) mode. In the instance of an organic light emitting display, the display panel 110 can be implemented in a top emission scheme, a bottom emission scheme, or a dual-emission scheme.

In the display panel 110, a plurality of pixels can be arranged in a matrix form, and each pixel can include subpixels SP having different colors, e.g., a white subpixel, a red subpixel, a green subpixel, and a blue subpixel. Each subpixel SP can be defined by the plurality of data lines DL and the plurality of gate lines GL.

Each subpixel SP can include, e.g., a thin film transistor (TFT) formed at the intersection between one data line DL and one gate line GL, a light emitting element, such as an organic light emitting diode, charged with the data voltage, and a storage capacitor electrically connected to the light emitting element to maintain the voltage.

For example, when the display device 100 having a resolution of 2,160×3,840 includes four subpixels SP of white (W), red (R), green (G), and blue (B), 3,840 data lines DL can be connected to 2,160 gate lines GL and four subpixels WRGB, and thus, there can be provided 3,840×4=15,360 data lines DL. Each subpixel SP is disposed at the intersection between the gate line GL and the data line DL.

The gate driving circuit 120 can be controlled by the controller 140 to sequentially output scan signals to the plurality of gate lines GL disposed in the display panel 110, controlling the driving timing of the plurality of subpixels SP.

In the display device 100 having a resolution of 2,160×3,840, sequentially outputting the scan signal to the 2,160 gate lines GL from the first gate line to the 2,160th gate line can be referred to as 2,160-phase driving. Sequentially outputting the scan signal to each unit of four gate lines GL, e.g., sequentially outputting the scan signal to the fifth gate line to the eighth gate line after sequentially outputting the scan signal to the first gate line to the fourth gate line, is referred to as 4-phase driving. In other words, sequentially outputting the scan signal to every N gate lines GL can be referred to as N-phase driving. In embodiments, N is an integer.

The gate driving circuit 120 can include one or more gate driving integrated circuits (GDICs). Depending on driving schemes, the gate driving circuit 120 can be positioned on only one side, or each of two opposite sides, of the display panel 110. However, other variations are possible. The gate driving circuit 120 can be implemented in a gate-in-panel (GIP) form which is embedded in the bezel area of the display panel 110.

The data driving circuit 130 receives image data from the timing controller 140 and converts the received image data DATA into an analog data voltage. Then, as the data voltage is output to each data line DL according to the timing when the scan signal is applied through the gate line GL, each subpixel SP connected to the data line DL displays a light emitting signal having the brightness corresponding to the data voltage.

Likewise, the data driving circuit 130 can include one or more source driving integrated circuits (SDICs), and the source driving integrated circuit (SDIC) can be connected to the bonding pad of the display panel 110 in a tape automated bonding (TAB) type or a chip-on-glass (COG) type or can be disposed directly on the display panel 110.

In some instances, each source driving integrated circuit (SDIC) can be integrated and disposed on the display panel 110. Further, each source driving integrated circuit (SDIC) can be implemented in a chip-on-film (COF) type and, in this instance, each source driving integrated circuit (SDIC) can be mounted on a circuit film and can be electrically connected to the data line DL of the display panel 110 through the circuit film.

The timing controller 140 supplies various control signals to the gate driving circuit 120 and the data driving circuit 130 and controls the operation of the gate driving circuit 120 and the data driving circuit 130. In other words, the timing controller 140 can control the gate driving circuit 120 to output a scan signal according to the timing implemented in each frame and, on the other hand, transfers the image data DATA received from the outside to the data driving circuit 130.

In this instance, the timing controller 140 receives, from an external host system 200, several timing signals including, e.g., a vertical synchronization signal Vsync, a horizontal synchronization signal Hsync, a data enable signal DE, and a main clock MCLK, together with the image data DATA.

The host system 200 can be any electricity using device, and can include any one of a television (TV) system, a set-top box, a navigation system, a personal computer (PC), a laptop, a home theater system, a mobile device, a wearable device, appliances, vehicles, or other mobile or stationary electronic devices, but is not limited hereto and can include other variations.

Accordingly, the timing controller 140 can generate a control signal according to various timing signals received from the host system 200 and transfers the control signal to the gate driving circuit 120 and the data driving circuit 130.

For example, the timing controller 140 outputs several gate control signals including, e.g., a gate start pulse GSP, a gate clock GCLK, and a gate output enable signal GOE, to control the gate driving circuit 120. The gate start pulse GSP controls the timing at which one or more gate driving integrated circuits (GDICs) constituting the gate driving circuit 120 start operation. The gate clock GCLK is a clock signal commonly input to one or more gate driving integrated circuits (GDICs) and controls the shift timing of the scan signal. The gate output enable signal GOE designates timing information about one or more gate driving integrated circuits (GDICs).

The timing controller 140 outputs various data control signals including, e.g., a source start pulse SSP, a source sampling clock SCLK, and a source output enable signal SOE, to control the data driving circuit 130. The source start pulse SSP controls the timing at which one or more source driving integrated circuits (SDICs) constituting the data driving circuit 130 start data sampling. The source sampling clock SCLK is a clock signal that controls the timing of sampling data in the source driving integrated circuit (SDIC). The source output enable signal SOE controls the output timing of the data driving circuit 130.

The display device 100 can further include the power management circuit 150 that supplies various voltages or currents to, e.g., the display panel 110, the gate driving circuit 120, and the data driving circuit 130 or controls various voltages or currents to be supplied.

The power management circuit 150 adjusts the direct current (DC) input voltage Vin supplied from the host system 200, generating power needed to drive the display panel 100, the gate driving circuit 120, and the data driving circuit 130.

The subpixel SP is positioned at the intersection between the gate line GL and the data line DL, and a light emitting element can be disposed in each subpixel SP. For example, the organic light emitting display can include a light emitting element, such as an organic light emitting diode, in each subpixel SP and can display an image by controlling the current flowing to the light emitting element according to the data voltage.

The display device 100 can be one of various types of devices, such as liquid crystal displays, organic light emitting displays, plasma display panels, etc.

When the display device 100 is an organic light emitting display, the display panel 110 includes a light emitting layer constituting an organic light emitting diode.

A mask is used to form such a light emitting layer. However, since mask drooping may occur in a process of forming a light emitting layer by a mask, and thus a yield may be lowered. Thus, a mask support for preventing mask drooping may be needed.

When the light emitting layer is deposited, the display device 100 uses a metal mask having an opening corresponding to the deposition site. When a metal mask meets the bank dividing the subpixels, the metal mask may cause the bank to sag or cause particles.

To address such issues, a spacer can be formed on the bank to prevent the surface of the metal mask from directly contacting the bank while supporting the metal mask.

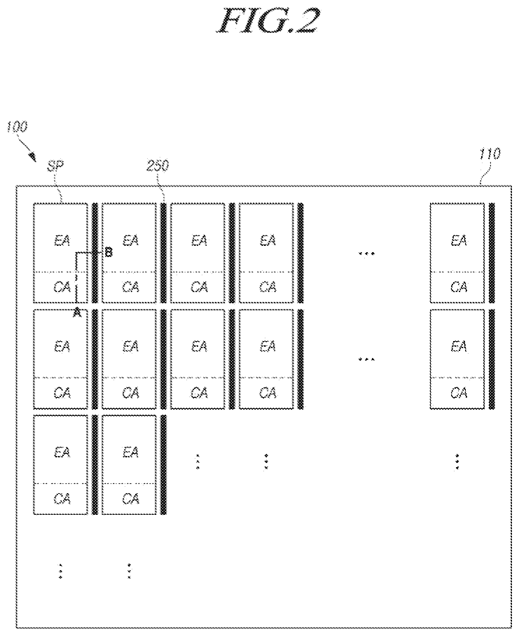

FIG. 2 is a view exemplarily illustrating a configuration in which a plurality of subpixels and spacers are arranged in a display panel of a display device according to embodiments of the disclosure.

Referring to FIG. 2, the display device 100 according to embodiments of the disclosure can include a display panel 110. The display panel 110 can include a plurality of subpixels SP arranged in a matrix type.

Here, the configuration in which the plurality of subpixels SP are arranged in a matrix type is illustrated, but this is merely an example and the plurality of subpixels SP in the display panel 110 according to embodiments of the disclosure can have other various arrangements.

At least one signal line can be positioned between one subpixel SP and another subpixel SP adjacent thereto. For example, any one of the data line DL and the gate line GL, or a reference voltage line or a driving voltage line can be disposed.

Each subpixel SP can include an emission area EA and a circuit area CA in which circuits for driving the light emitting element are positioned.

In the display panel 110, an area other than the emission area EA included in the subpixel SP can be a non-emission area NEA.

Depending on the emission direction of the light from the light emitting layer, the display device 100 can be divided into a front emission display device and a back emission display device. The back emission display device emits light toward the substrate having thin film transistors, and the front emission display device emits light in the direction opposite from the substrate having thin film transistors.

Accordingly, when the display device of the disclosure is configured as a front emission display device, the emission area EA and the circuit area CA can be disposed to overlap each other.

The display panel 110 according to embodiments of the disclosure can include at least one spacer 250.

The spacer 250 can be disposed on one side of the at least one subpixel SP. In this instance, the spacer 250 can be disposed to overlap a signal line disposed on at least one side of the subpixel SP, or can be positioned in the circuit area CA within the subpixel SP. In other words, the spacer 250 can be positioned in the remaining area, i.e., the non-emission area that is distinct from the emission area EA.

Illustrated is an example in which the spacer 250 is disposed to overlap the signal line disposed on at least one side of the subpixel SP, but without being limited thereto, the spacer 250 can be disposed in various positions in the non-emission area NEA.

As such, as the spacer 250 can be positioned not to block the emission area EA, and a reduction in the emission area EA due to the spacer 250 can be prevented.

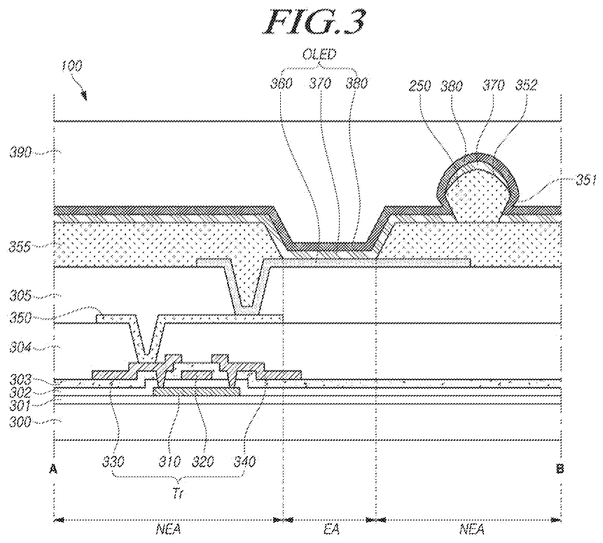

FIG. 3 is a cross-sectional view exemplarily illustrating a display panel according to embodiments of the disclosure. A cross section taken along A-B of FIG. 2 is illustrated in FIG. 3.

Referring to FIG. 3, the display device 100 according to embodiments of the disclosure can include a thin film transistor Tr disposed on a substrate 300, an organic light emitting diode OLED electrically connected to the thin film transistor Tr, and a spacer 250 disposed in the non-emission area NEA. Illustrated is an example organic light emitting display device in which the organic light emitting diode OLED constitutes the light emitting element.

The thin film transistor Tr corresponds to a circuit element including an active layer 310, a gate electrode 320, a source electrode 330, and a drain electrode 340. The organic light emitting diode OLED includes a first electrode 360, a light emitting layer 370, and a second electrode 380.

The first electrode 360 can be an anode electrode and the second electrode 380 can be a cathode electrode. Alternatively, the first electrode 360 can be a cathode electrode and the second electrode 380 can be an anode electrode. Described below is an example in which the first electrode 360 is an anode electrode, and the second electrode 380 is a cathode electrode.

A buffer layer 301 can be disposed on the substrate 300. An active layer 310 can be disposed on the buffer layer 301. A gate insulation film 302 can be disposed on the active layer. A gate electrode 320 overlapping the active layer 310 can be disposed on the gate insulation film 302.

An inter-layer insulation film 303 can be disposed on the gate electrode 320. A source electrode 330 and a drain electrode 340 connected to the active layer 310 through a contact hole provided in the inter-layer insulation film 303 and the gate insulation film 302 can be disposed on the inter-layer insulation film 303.

The configuration in which the gate electrode 320 is disposed on the active layer 310 is illustrated but, without being limited thereto, the active layer 310 can be disposed on the gate electrode 320.

The source electrode 330 and the drain electrode 340 can be formed of a source-drain metal of the same material, and a first overcoat layer 304 can be disposed on the source electrode 330 and the drain electrode 340.

A second source-drain electrode 350 electrically connected to the source electrode 330 or the drain electrode 340 of the thin film transistor Tr through a contact hole can be formed on the first overcoat layer 304.

A second overcoat layer 305 can be disposed on the second source-drain electrode 350.

A first electrode 360 of the organic light emitting diode OLED can be disposed on the second overcoat layer 305. The first electrode 360 can be electrically connected to the source electrode 330 or the drain electrode 340 of the thin film transistor Tr through the second source-drain electrode 350.

In this instance, the second source-drain electrode 350 and the second overcoat layer 305 can be omitted. As such, when the second source-drain electrode 350 and the second overcoat layer 305 are omitted, the first electrode 360 can be electrically connected directly to the source electrode 330 or the drain electrode 340 of the thin film transistor Tr.

Illustrated is a configuration in which the first electrode 360 is connected to the source electrode 330 of the thin film transistor Tr but, without being limited thereto, can be connected to the drain electrode 340.

A bank 355 can be disposed on the second overcoat layer 305 and the first electrode 360. The bank 355 can divide an emission area EA and a non-emission area NEA. Specifically, an area corresponding to an area where the bank 355 is positioned can correspond to the non-emission area NEA, and an area corresponding to an area where the bank 355 is not positioned can correspond to the emission area EA.

The bank 355 can be disposed to expose a portion of the upper surface of the first electrode 360. At least one spacer 250 is positioned on the bank 355.

A light emitting layer 370 can be disposed on the bank 355, the upper surface of the first electrode 360 exposed by the bank 355, and a portion of the outer portion of the spacer 250. A second electrode 380 can be disposed on the light emitting layer 370 and the spacer 250.

An encapsulation layer 390 for protecting the organic light emitting diode OLED from foreign substances, such as moisture, can be disposed on the second electrode 380.

Illustrated is a configuration in which the encapsulation layer 390 is a single layer but, without being limited thereto, the encapsulation layer 390 can have a multi-layer structure. When the encapsulation layer 390 has a multi-layer structure, an organic layer and an inorganic layer can be alternately disposed.

A first outer portion 351 of the spacer 250 can have a reversely tapered shape that increases in width away from the substrate 100, and a second outer portion 352 thereof can have a portion that decreases in width as it moves away from the substrate 100 but can selectively include a portion having a positively tapered shape that reduces in width away from the substrate 100 or a convex portion.

The second outer portion 352 of the spacer 250 can serve to support a mask used when forming the light emitting layer 370 on the substrate 300.

In this instance, since the side surface of the second outer portion 352 includes a portion having a positively tapered shape or a convex portion, the area in which the second outer portion 352 contacts the mask can be reduced. For example, the second outer portion 352 and the mask can be in point contact with each other.

Further, since the first outer portion 351 of the spacer 250 has a reversely tapered shape, the light emitting layer 370 can be disposed to partially expose the outer portion of the spacer 250.

Specifically, the light emitting layer 370 can be disposed to expose the whole or part of the first outer portion 351 of the spacer 250, and be disposed on the second outer portion 352 of the spacer 250.

The above-described structure comes from the outer shape of the spacer 250 and the process characteristics of the light emitting layer 370.

The light emitting layer 370 can be formed on the substrate 100 where the first electrode 360, the bank 355, and the spacer 250 are disposed. The light emitting layer 370 can be formed by deposition or coating featuring straightness. For example, the light emitting layer 370 can be formed by evaporation.

To form the light emitting layer 370 in this way, the material of the light emitting layer 370 can be evaporated in the chamber. In the chamber, the material of the light emitting layer 370 can be positioned to face the first electrode 360, the bank 355, and the spacer 250, with a gap left therebetween.

The material of the light emitting layer 370 evaporated while having straightness in the chamber can be directed toward the substrate 100 where the first electrode 360, the bank 355, and the spacer 250 are disposed.

The material of the light emitting layer 370 builds on the bank 355, the upper surface of the first electrode 360 exposed by the bank 355, and the second outer portion 352 of the spacer 250, forming the light emitting layer 370.

It is difficult for the material of the light emitting layer 370 to reach the first outer portion 351 above the area where the spacer 250 has the maximum width in the chamber. In other words, since the maximum-width area of the spacer 250 blocks the whole or part of the material of the light emitting layer evaporated straight, the material of the light emitting layer 370 can fail to reach the first outer portion 351 or can reach only a portion of the first outer portion 351.

Accordingly, the finally formed light emitting layer 370 can be disposed to expose the whole or part of the first outer portion 351 of the spacer 250.

The second electrode 380 can be formed in such a way that the directionality of the deposition material is not constant. For example, the second electrode 380 can be formed by sputtering.

Sputtering presents superior step coverage and thus allows the material to be deposited along the outer shape of the substrate 300 where it is deposited. Accordingly, despite the presence of the spacer 250 including the reversely-tapered first outer portion 351 on the substrate 300, the second electrode 380 can be formed along the surface of the first outer portion 351.

Thus, the finally formed second electrode 380 can be positioned on the light emitting layer 370 and the first outer portion 351 and the second outer portion 352 of the spacer 250. Specifically, the second electrode 380 can be disposed to contact the first outer portion 351 of the spacer 250 exposed by the light emitting layer 370.

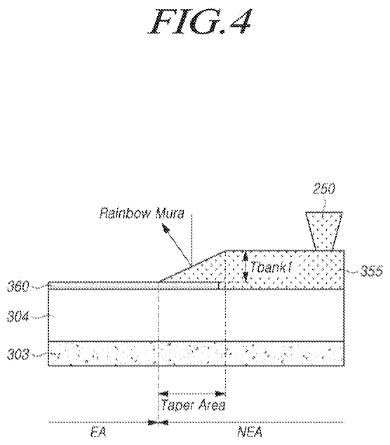

FIG. 4 is a view exemplarily illustrating a cross section of an emission area and a non-emission area in a display panel of a display device.

Referring to FIG. 4, in the display panel 110 of the display device 100, the first electrode 360 and the bank 355 of the organic light emitting diode OLED can be formed on the inter-layer insulation film 303 and the overcoat layer 304.

Illustrated is an example in which the second source-drain electrode 350 and the second overcoat layer 305 have been omitted.

In this instance, the emission area EA and the non-emission area NEA of the display panel 110 can be divided by the bank 355. In other words, the bank 355 is formed in the non-emission area NEA, and he first electrode 360 of the organic light emitting diode OLED is formed in the emission area EA.

Thus, the bank 355 forms a first height Tbank1 from the first electrode 360 in the non-emission area NEA, so that a taper area having a predetermined slope is formed at the boundary between the emission area EA and the non-emission area NEA. The first height Tbank1 can be in a range of about 1 to 2 μm, and an angle of the predetermined slope can be less than about 15 degrees.

In this instance, the bank 355 can be formed of an organic material, and use of the organic material has a disadvantage in that it is difficult to form a small thickness or increase the slope of the taper area due to the characteristics of the material.

For example, as the thickness of the bank 355 increases, it becomes more difficult to increase the slope of the taper area due to the tendency of the slope of the tapered area to decrease. Therefore, to increase the slope of the taper area when a black bank 355 is used, it is required to reduce the thickness of the bank 355, and this increase a chance of a defect between the first electrode 360 and the second electrode 380.

Further, even upon forming the bank 355 with a negative material to cure the light-irradiated area, it is harder to form the slope of the taper area at a predetermined angle or more due to the characteristics of the negative material.

Thus, when the taper area of the bank 355 is formed at a small angle which is a predetermined slope or less, the light incoming from above is reflected by the taper area to the second electrode formed on the first electrode 360, causing light dispersion like a rainbow, referred to as a mura. In embodiments of the disclosure, the mura can be referred to as a rainbow mura.

In the display device 100 of the disclosure, a metal pattern (or a taper pattern) can be disposed at a lower portion of a layer overlapping the taper area, thereby allowing the taper area to have a slope of a reference value or more and preventing or reducing image quality deterioration, such as the rainbow mura.

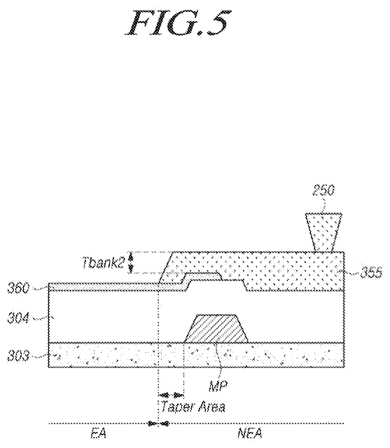

FIG. 5 is a view exemplarily illustrating a cross section of an emission area and a non-emission area in a display device according to embodiments of the disclosure.

Referring to FIG. 5, the display device 100 according to embodiments of the disclosure can include a thin film transistor Tr disposed on a substrate 300, an organic light emitting diode OLED electrically connected to the thin film transistor Tr, and a spacer 250 disposed in the non-emission area NEA.

The thin film transistor Tr includes an active layer 310, a gate electrode 320, a source electrode 330, and a drain electrode 340. The organic light emitting diode OLED includes a first electrode 360, a light emitting layer 370, and a second electrode 380.

An inter-layer insulation film 303 can be disposed on the gate electrode 320. A source electrode 330 and a drain electrode 340 connected to the active layer 310 through a contact hole provided in the inter-layer insulation film 303 and the gate insulation film 302 can be disposed on the inter-layer insulation film 303, forming a thin film transistor Tr. Illustrated is an example in which the second source-drain electrode 350 and the second overcoat layer 305 have been omitted, but in other embodiments, the second source-drain electrode 350 and the second overcoat layer 305 can be included.

In the display device 100 of the embodiment of the disclosure, a metal pattern MP can be further formed in the position overlapping at least a portion of the taper area of the bank 355. In other words, the metal pattern MP can be disposed on the inter-layer insulation film 303 to at least partially overlap the taper area of the bank 355.

When the metal pattern MP is disposed in the same layer as the source electrode 330 and the drain electrode 340 of the thin film transistor Tr on the inter-layer insulation film 303, the metal pattern MP can be formed of the same metal as the source electrode 330 and the drain electrode 340. The metal pattern MP can be formed simultaneously with the source electrode 330 and the drain electrode 340 or during the same forming operation. The metal pattern MP can have the same thickness as that of the source electrode 330 and/or the drain electrode 340, but such is not required, and can have a different thickness.

As described above, the first overcoat layer 304 can be disposed on the source electrode 330 and the drain electrode 340, and the second source-drain electrode 350 electrically connected to the source electrode 330 or the drain electrode 340 of the thin film transistor Tr through a contact hole can be formed on the first overcoat layer 304.

In this instance, the metal pattern MP can be disposed on the first overcoat layer 304 to at least partially overlap the taper area of the bank 355.

When the metal pattern MP is disposed in the same layer as the second source-drain electrode 350 on the first overcoat layer 304, the metal pattern MP can be formed of the same material as that of the second source-drain electrode 350.

Since the metal pattern MP is disposed along the taper area of the bank 355, it can be disposed on or near the edge of the emission area EA.

The overcoat layer 304 is disposed on the metal pattern MP. The overcoat layer 304 is formed to protrude to a predetermined height in the taper area due to the thickness of the metal pattern MP.

The first electrode 360 and the bank 355 of the organic light emitting diode OLED can be formed on the overcoat layer 304. In this instance, the emission area EA and the non-emission area NEA of the display panel 110 are divided by the bank 355, and the bank 355 is formed in the non-emission area NEA.

The bank 355 is formed at a predetermined height in the non-emission area NEA, so that a taper area having a predetermined slope is formed at or immediately adjacent the boundary between the emission area EA and the non-emission area NEA

In this instance, since the taper area of the bank 355 corresponds to a position overlapping the metal pattern MP formed thereunder, the taper area is formed to protrude upward by the metal pattern MP and the protruding overcoat layer 304.

As a result, the slope of the taper area can be increased, and a mura caused by light reflection can be reduced. The increased slope of the taper area of the bank 355 can be about 15 degrees or greater. For example, the increased slope can be between 15 and 20 degrees, and any angle in between or even greater.

As described above, when the metal pattern MP is disposed at a lower portion of a layer overlapping the taper area, it is possible to increase the slope of the taper area regardless of the thickness of the bank 355.

For example, when forming a black bank 355, it is possible to reduce the thickness of the black bank 355 overlapping the metal pattern MP by disposing the metal pattern MP at a lower portion of a layer overlapping the taper area. In other words, the second thickness Tbank2 at or adjacent the taper area can be smaller than the first thickness Tbank1 at a non-taper area of FIG. 4. The second thickness Tbank2 can be in a range of about 0.1 to 0.5 μm, but such is not required, and the second thickness Tbank2 can be about the same or less than that of the first thickness Tbank1.

Accordingly, in the process of forming the black bank 355, the light transmittance of the black bank 355 overlapping the metal pattern MP is enhanced, so that light curing can occur relatively well or can be improved. Further, since light is reflected from the metal pattern MP, light curing of the black bank 355 adjacent to the metal pattern MP can also occur relatively well or can be improved. Accordingly, the flow-down phenomenon of the black bank 355 can be reduced, and it is possible to increase the slope of the taper area of the black bank 355.

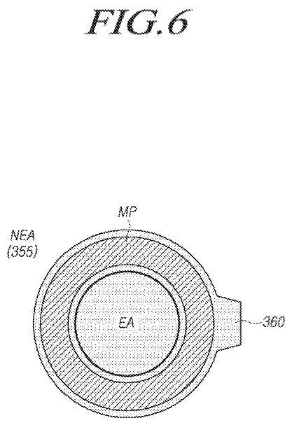

FIG. 6 is a plan view exemplarily illustrating an emission area where a metal pattern is disposed in a display device according to embodiments of the disclosure.

Referring to FIG. 6, in the display device 100 according to embodiments of the disclosure, an emission area EA and a non-emission area NEA of the display panel 110 can be divided by a bank 355. In other words, the bank 355 is formed in the non-emission area NEA, and the first electrode 360 of the organic light emitting diode OLED is formed in the emission area EA.

In this instance, the boundary portion between the emission area EA and the non-emission area NEA begins a taper area where the bank 355 is formed with a constant slope, and a first electrode 360 and a metal pattern MP can be disposed at or adjacent the taper area. In embodiments of the disclosure, the metal pattern MP can overlap the taper area or can be just outside the taper area.

In other words, in the display device 100 of the disclosure, the taper area of the bank 355 is disposed to overlap at least a portion of the metal pattern MP. Accordingly, when the emission area EA is formed in a circular shape, the taper area of the bank 355 can be disposed in a circular shape along the periphery of the emission area EA, and the metal pattern MP can be disposed in a circular shape in a position overlapping the taper area.

As a result, the slope of the taper area of the bank 355 formed along the periphery of the emission area EA can be increased, mitigating a mura caused by the light coming in from the outside.

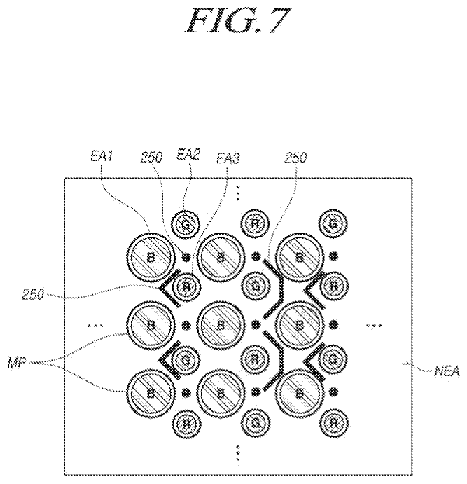

FIG. 7 is a view exemplarily illustrating an arrangement of subpixels and a metal pattern in a display device according to embodiments of the disclosure.

Substantially the same configurations and effects as those described above are not repeatedly described below.

Referring to FIG. 7, a display device 100 according to embodiments of the disclosure can include a plurality of first emission areas EA1 emitting a first color of light, a plurality of second emission areas EA2 emitting a second color of light, and a third emission areas EA3 emitting a third color of light.

In this instance, the first emission areas EA1 can be arranged in a matrix type. Further, the emission areas EA2 and EA3 smaller in area than the first emission areas EA1 and emitting light of a color different from that of the first emission areas EA1 can be disposed between the first emission areas EA1.

For example, a second emission area EA2 or a third emission area EA3 can be disposed in the center of the four first emission areas EA1. For example, as shown in FIG. 7, four first emission areas EA1 can be located at four locations encircling one second emission area EA2 or one third emission area EA3.

The first emission area EA1, the second emission area EA2, and the third emission area EA3 can emit blue light B, red light R, and green light G, respectively but, without being limited thereto, each emission area EA1, EA2, and EA3 can emit a different color of light.

As described above, since the areas of the emission areas EA1, EA2, and EA3 emitting different colors of light are formed to have different areas, the luminance lifespan of the first emission area EA1 can be rendered equal to the luminance lifespan of the first and second emission areas EA2 and EA3, and a change in the color of the display device 100 can be minimized.

For example, when the lifespan of an organic light emitting diode OLED emitting a first color of light is shorter than the lifespan of organic light emitting diodes OLED emitting a second color of light and a third color of light, the first emission area EA1 where the organic light emitting diode OLED emitting the first color of light can be rendered larger in area than the second and third emission areas EA2 and EA3.

Further, depending on the lifespan of the organic light emitting diodes OLED emitting the second and third colors of light, the second and third emission areas EA2 and EA3 can also be changed in area.

Illustrated is a configuration in which the first to third emission areas EA1, EA2, and EA3 are circular at plan view but, without being limited thereto, the first to third emission areas EA1, EA2, and EA3 can be formed in other various shapes, such as circles, ovals, or polygons at plan view.

Depending on the structure and shape of the emission areas EA1, EA2, and EA3, the structure and shape of the metal pattern MP formed in the position overlapping the taper area along the periphery of the emission areas EA1, EA2, and EA3 can be determined.

In other words, the metal pattern formed in the position of the taper area can be disposed to correspond to the structure of the first emission area EA1 along the periphery of the first emission area EA1 or be disposed to correspond to the structure of the second and third emission areas EA2 and EA3 along the periphery of the second and third emission areas EA2 and EA3 with a smaller area. Accordingly, although the shapes of the first to third emission areas EA1, EA2, and EA3 and the shapes of the metal pattern formed in the position of the taper area can be made to correspond, such is not required, and a shape of an emission area EA and a shape of the metal pattern MP for that emission area EA can be different. For example, for a circular emission area EA, a rectangular metal pattern MP can be used. Any combination of shapes for the emission area and the metal pattern MP can be used.

A spacer 250 can be disposed in the non-emission area NEA of the display device 100. The spacer 250 can be disposed only in a partial area of the non-emission area NEA. In this instance, the shape and size of the spacer 250 can be varied. The spacer 250 can have at least one shape of a dote, a circle, oval, a polygon, a line, or a curve at plan view. Further, the spacer 250 can have various forms, shapes or lengths, and can be located between adjacent emission areas EA. Also, the spacer 250 having a length can include one or more angles or corners, and can have a shape that can partially enclose one or more of the emission areas EA. One or more of the spacers 250 can be arranged to enclose or partially enclose one or more of the emission areas EA, and can further act or be a barrier to light from one or more emission areas EA.

Meanwhile, since the size of the non-emission area NEA between the emission areas EA1, EA2, and EA3 disposed near each other can be different, the size of the area in which the spacer 250 can be disposed can be varied depending on which emission areas the spacer 250 is disposed between.

The metal pattern MP formed to overlap the taper area of the bank 355 along the periphery of the emission area EA can be formed not only in a continuous structure, but also in a discontinuous structure in which some sections are opened.

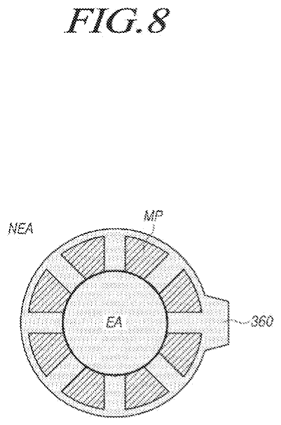

FIG. 8 is a plan view exemplarily illustrating an emission area where a metal pattern is disposed in a discontinuous structure in a display device according to embodiments of the disclosure.

Referring to FIG. 8, in the display device 100 according to embodiments of the disclosure, an emission area EA and a non-emission area NEA of the display panel 110 can be divided by a bank 355. In other words, the bank 355 is formed in the non-emission area NEA, and he first electrode 360 of the organic light emitting diode OLED is formed in the emission area EA.

In this instance, the boundary portion between the emission area EA and the non-emission area NEA corresponds to a taper area where the bank 355 is formed with a constant slope, and a first electrode 360 360 and a metal pattern MP can be disposed under the taper area.

In other words, in the display device 100 of the disclosure, the taper area of the bank 355 is disposed to overlap at least a portion of the metal pattern MP. Accordingly, when the emission area EA is formed in a circular shape, the taper area of the bank 355 can be disposed in a circular shape along the periphery of the emission area EA, and the metal pattern MP can be disposed in a circular shape in a position overlapping the taper area.

In this instance, the metal pattern MP disposed to overlap the taper area of the bank 355 along the periphery of the emission area EA can be formed in a discontinuous structure. In other words, the metal pattern MP can be separated into a plurality of segments. The plurality of separated segments can be positioned to overlap the taper area of the bank 355 along the outer edge or the periphery of the emission area EA along an axis of rotation. In embodiments of the disclosure, a cross sectional shape of the metal pattern MP can be a parallelogram, such as a trapezoid or a rectangle, but such is not required and other cross sectional shapes can be used. For example, the cross sectional shape of the metal pattern MP can include a semi-circle, a half-oval, a polygon, or other shapes. Additionally, the upper surface of the metal pattern MP can be a flat surface, but such is not required. For example, the upper surface of the metal pattern MP can have a wave pattern, multiple pyramidal patterns, or other protrusions. Further, the metal pattern MP can be separated into a plurality of segments that are separated radially away from a center each emission area EA. The metal pattern MP can also have differing heights at different portions, either when the metal pattern MP is a single piece, or when the metal pattern MP is in the plurality of segments.

In this instance, the slope of the taper area in which the slope of the metal pattern MP formed of the plurality of segments is positioned is relatively large, whereas the slope of the taper area in which the metal pattern MP is not positioned is relatively small.

As a result, since the path of the light reflected from the taper area where the metal pattern MP is positioned and the light reflected from the taper area where the metal pattern MP is not positioned are different, diffuse reflection occurs, and the occurrence of a certain pattern of a mura can be reduced.

Thus, when the metal pattern MP disposed to overlap the taper area of the bank 355 along the periphery of the emission area EA is formed in a discontinuous structure, a mura due to the light incoming from the outside can further be mitigated.

Further, in the display device 100 of the disclosure, a mura caused by light reflection can be alleviated by additionally forming a taping spacer having a large slope in the taper area of the bank 355.

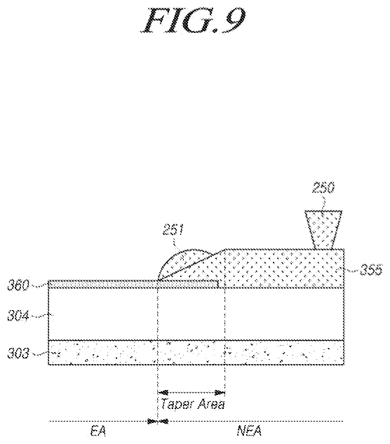

FIG. 9 is a view exemplarily illustrating a cross section when a taping spacer is formed in a taper area of a bank in a display device according to embodiments of the disclosure.

Referring to FIG. 9, the display device 100 according to embodiments of the disclosure can include a thin film transistor Tr disposed on a substrate 300, an organic light emitting diode OLED electrically connected to the thin film transistor Tr, and a spacer 250 disposed in the non-emission area NEA.

The thin film transistor Tr includes an active layer 310, a gate electrode 320, a source electrode 330, and a drain electrode 340. The organic light emitting diode OLED includes a first electrode 360, a light emitting layer 370, and a second electrode 380.

An inter-layer insulation film 303 is disposed on the gate electrode 320. A source electrode 330 and a drain electrode 340 connected to the active layer 310 through a contact hole provided in the inter-layer insulation film 303 and the gate insulation film 302 are disposed on the inter-layer insulation film 303, forming a thin film transistor Tr.

An overcoat layer 304 can be disposed on the inter-layer insulation film 303, and the first electrode 360 of the organic light emitting diode OLED and the bank 355 can be formed on the overcoat layer 304. In this instance, the emission area EA and the non-emission area NEA of the display panel 110 are divided by the bank 355, and the bank 355 is formed in the non-emission area NEA.

Illustrated is an example in which the second source-drain electrode 350 and the second overcoat layer 305 have been omitted.

The bank 355 is formed at a predetermined height in the non-emission area NEA, so that a taper area having a predetermined slope is formed at the boundary between the emission area EA and the non-emission area NEA

Further, in the display device 100 of the disclosure, a taping spacer 251 having a large or varying slope is additionally formed in the taper area of the bank 355. In other words, since the taping spacer 251 is disposed to protrude in the taper area of the bank 355, the slope of the taper area can be greatly increased or be greatly varying. In embodiments of the disclosure, the taping spacer 251 can have an angle or a slope that is greater than 20 degree. For example, the taping spacer can have the slope that is about 40 degrees or greater, such as 40 degrees to 90 degrees, and any angle in between or greater. Further, an outer surface of the taping spacer 251 can be curved, and can have a curvature that can be constant or vary in going outward from the emission area EA towards the non-emission area NEA.

The taping spacer 251 can be disposed adjacent to the emission area EA in the taper area of the bank 355.

The taping spacer 251 can be formed of the same material as the spacer 250 formed on the bank 355 through the same photolithography process as forms the spacer 250.

In other words, a material for forming the taping spacer 251 and the spacer 250 can be deposited over the taper area and the bank 355 and be irradiated with light with a mask pattern placed, simultaneously forming the taping spacer 251 in the taper area and the spacer 250 on the bank 355.

As described above, the taper area is formed to protrude at a predetermined height by the taping spacer 251 additionally disposed in the taper area of the bank 355.

As a result, the slope of the taper area can be increased, and a mura caused by light reflection can be reduced.

As described above, when the taping spacer 251 is additionally disposed on the taper area, it is possible to increase the slope of the taper area regardless of the thickness of the bank 355.

For example, upon forming a black bank 355, it is possible to increase the slope of the taper area even without reducing the thickness of the bank 355 by additionally disposing the taping spacer 251 on the taper area.

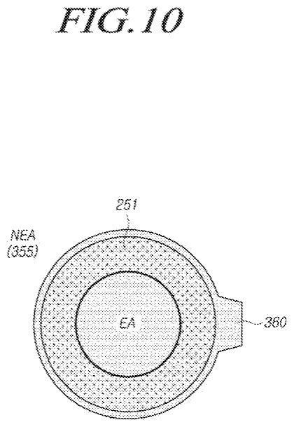

FIG. 10 is a plan view exemplarily illustrating an emission area where a taping spacer is disposed in a display device according to embodiments of the disclosure.

Referring to FIG. 10, in the display device 100 according to embodiments of the disclosure, an emission area EA and a non-emission area NEA of the display panel 110 can be divided by a bank 355. In other words, the bank 355 is formed in the non-emission area NEA, and he first electrode 360 of the organic light emitting diode OLED is formed in the emission area EA.

In this instance, the boundary portion between the emission area EA and the non-emission area NEA corresponds to a taper area where the bank 355 is formed with a constant slope, and the taping spacer 251 can additionally be disposed in the taper area.

In other words, in the display device 100 of the disclosure, the taping spacer 251 is additionally disposed in at least a portion of the taper area of the bank 355. For example, the taping spacer 251 can be additionally disposed in a portion adjacent to the emission area EA. Accordingly, when the emission area EA is formed in a circular shape, the taper area of the bank 355 can be disposed in a circular shape along the periphery of the emission area EA, and a circular taping spacer 251 can be disposed on the taper area.

As a result, the slope of the taper area of the bank 355 formed along the periphery of the emission area EA can be increased, mitigating a mura caused by the light coming in from the outside.

It is possible to adjust the thickness, according to the position, of the taping spacer 251 formed in the taper area of the bank 355, by way of a mask pattern. Accordingly, it is possible to further increase the slope of the taper area by increasing the thickness of the portion adjacent to the emission area EA using a mask pattern.

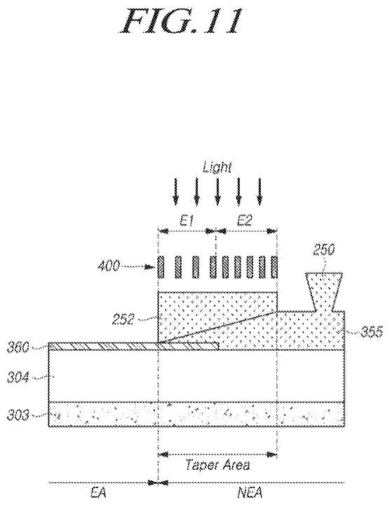

FIG. 11 is a view exemplarily illustrating a process of adjusting the thickness of a taping spacer using a mask pattern in a display device according to embodiments of the disclosure.

Referring to FIG. 11, the display device 100 according to embodiments of the disclosure can include a thin film transistor Tr disposed on a substrate 300, an organic light emitting diode OLED electrically connected to the thin film transistor Tr, and a spacer 250 disposed in the non-emission area NEA.

The bank 355 is formed at a predetermined height in the non-emission area NEA, so that a taper area having a predetermined slope is formed at the boundary between the emission area EA and the non-emission area NEA

In the display device 100 of the disclosure, a taping spacer 251 (see FIG. 9) can be additionally formed in the taper area of the bank 355 from a taping spacer material 252.

To this end, a taping spacer material 252 is applied to the taper area of the bank 355 formed to have a predetermined slope. The taping spacer material 252 can be the same material as the spacer 250 on the bank 355.

In a state in which the taping spacer material 252 is applied to the taper area, a photolithography process of radiating light to the taping spacer material 252 is performed using the mask pattern 400.

The mask pattern 400 can be divided into a transmissive area through which light is transmitted and a non-transmissive area through which light is blocked.

When the taping spacer material 252 is a negative material, the curing degree of the area irradiated with more light is higher, and the curing degree of the area irradiated with less light is lower. Accordingly, the slope of the portion irradiated with more light in the taping spacer material 252 is increased and the slope of the portion irradiated with less light is decreased. In contrast, when the taping spacer material 252 is a positive material, the curing degree of the area irradiated with more light is lower and the curing degree of the area irradiated with less light is higher.

Since the height of the portion adjacent to the emission area EA in the taper area is smaller, it is preferable to increase the slope of the taping spacer 251. Since the height of the portion adjacent to the non-emission area NEA is larger, it is preferable to decrease the slope of the taping spacer 251.

Accordingly, the first slope area E1 of the mask pattern 400, which is closer to the emission area EA, can be formed to have a larger transmissive area, and the second slope area E2, which is closer to the non-emission area NEA, can be formed to have a smaller transmissive area.

Illustrated is an example in which the transmissive area of the mask pattern 400 is varied depending on the first slope area E1 and the second slope area E2 but, without being limited thereto, the mask pattern 400 can be divided into three or more transmissive areas, and various changes can be made to the size of each transmissive area.

The taping spacer 251, cured by the light radiation to the taping spacer material 252 through the mask pattern 400, is disposed to protrude in the taper area of the bank 355, thus significantly increasing the slope of the taper area.

In the taping spacer 251, the portion adjacent to the emission area EA in the taper area of the bank 355 can be larger in slope than the portion adjacent to the non-emission area NEA.

The taping spacer 251 can be formed of the same material as the spacer 250 formed on the bank 355 through the same photolithography process as forms the spacer 250.

In other words, a material for forming the taping spacer 251 and the spacer 250 can be deposited over the taper area and the bank 355 and be irradiated with light with a mask pattern placed, simultaneously forming the taping spacer 251 in the taper area and the spacer 250 on the bank 355. But, such is not required, and the spacer 250 and the taping spacer 251 may be formed at different times or in different sequences.

As described above, the taper area is formed to protrude at a predetermined height by the taping spacer 251 additionally disposed in the taper area of the bank 355. As a result, the slope of the taper area can be increased, and a mura caused by light reflection can be reduced.

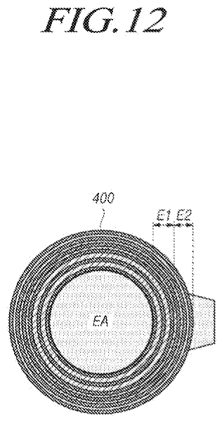

FIG. 12 is a plan view exemplarily illustrating a mask pattern for forming a taping spacer in a display device according to embodiments of the disclosure.

Referring to FIG. 12, in the display device 100 according to embodiments of the disclosure, an emission area EA and a non-emission area NEA of the display panel 110 can be divided by a bank 355. In other words, the bank 355 is formed in the non-emission area NEA, and he first electrode 360 of the organic light emitting diode OLED is formed in the emission area EA.

In this instance, the boundary portion between the emission area EA and the non-emission area NEA corresponds to a taper area where the bank 355 is formed with a constant slope, and the taping spacer 251 can additionally be disposed in the taper area.

In other words, in the display device 100 of the disclosure, the taping spacer 251 is additionally disposed in at least a portion of the taper area of the bank 355. Accordingly, when the emission area EA is formed in a circular shape, the taper area of the bank 355 can be disposed in a circular shape along the periphery of the emission area EA, and a circular taping spacer 251 can be disposed on the taper area.

In this instance, the taping spacer 251 formed on the taper area can be controlled to have a different slope depending on the position.

For example, as the height of the taper area adjacent to the emission area EA is smaller, the slope of the taping spacer 251 can be increased and, as the height of the portion adjacent to the non-emission area NEA is larger, the slope of the taping spacer 251 adjacent to the non-emission area NEA can be decreased.

Accordingly, when a negative material is used as the taping spacer material 252, the first slope area E1 of the mask pattern 400, which is closer to the emission area EA, can be formed to have a larger transmissive area, and the second slope area E2, which is closer to the non-emission area NEA, can be formed to have a smaller transmissive area.

The foregoing examples increase the slope of the taper area by forming a metal pattern in a portion overlapping the taper area or forming a taping spacer 251 on the taper area. Accordingly, the metal pattern MP and the taping spacer 251 can be referred to as taper control elements. Further, the metal pattern MP and the taping spacer 251 can be present separately, or in other embodiments of the disclosure, can be present simultaneously in a display device 100.

As a result, the slope of the taper area formed along the periphery of the emission area EA can be increased, mitigating a mura caused by the light coming in from the outside.

The foregoing embodiments are briefly described below.

A display device 100 according to embodiments of the disclosure can comprise a substrate 300, a circuit element disposed on the substrate 300, a light emitting element electrically connected to the circuit element and including a first electrode 360, a light emitting layer 370, and a second electrode 380, a bank 355 disposed to form an emission area EA as a portion of an upper surface of the first electrode 360 is exposed, at least one spacer 250 disposed on the bank 355, and a taper control element disposed in at least a partial area overlapping a taper area of the bank 355 to increase a slope of the taper area of the bank 355 adjacent to the emission area EA.

The bank 355 can be formed of a black material.

The taper control element can be formed to overlap at least a partial area of the taper area, under the bank 355.

The taper control element can be formed of a same metal as a source electrode 330 and a drain electrode 340 constituting the circuit element.

The display device 100 can further comprise a buffer layer 301 formed on the substrate 300, a gate insulation film 302 formed on the buffer layer 301, and an inter-layer insulation film 303 formed on the gate insulation film 302. The taper control element can be formed on the inter-layer insulation film 303.

The taper control element can be formed in a same layer as a source electrode and a drain electrode constituting the circuit element.

The display device 100 can further comprise a buffer layer 301 formed on the substrate 300, a gate insulation film 302 formed on the buffer layer 302, an inter-layer insulation film 303 formed on the gate insulation film 302, and an overcoat layer 304 formed on the inter-layer insulation film 303. The taper control element can be formed on the overcoat layer 304.

The taper control element can be formed in a same layer as a second source-drain electrode 350 connected to a source electrode or a drain electrode constituting the circuit element, on the overcoat layer 304.

The taper control element can be formed in a continuous structure along a periphery of the emission area EA.

The taper control element can be separated into a plurality of segments to be formed in a discontinuous structure along a periphery of the emission area EA.

The taper control element can be a taping spacer 251 formed to overlap at least a partial area of the taper area, on the bank 355.

The taping spacer 251 can be formed of a same material as the spacer 250.

The taping spacer 251 can be divided into a plurality of areas having different slopes depending on positions.

The taping spacer 251 can be formed by a same lithography process as the spacer 250.

The taping spacer 251 can include a first slope area E1 having a first slope, adjacent to the emission area EA, and a second slope area E2 having a second slope smaller than the first slope.

The first slope area E1 can be cured by light radiated through a first transmissive area of a mask pattern 400, and the second slope area E2 can be cured by light radiated through a second transmissive area of the mask pattern 400.

The first transmissive area can be formed to be larger than the second transmissive area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

Thus, the scope of the disclosure is not limited to the embodiments shown, but is to be accorded the widest scope consistent with the claims. The scope of protection of the disclosure should be construed based on the following claims, and all technical ideas within the scope of equivalents thereof should be construed as being included within the scope of the disclosure.

What is claimed is:

1. A display device comprising:
a substrate including an emission area and a non-emission area;
a circuit element on the substrate;
a light emitting element electrically connected to the circuit element and including a first electrode, a light emitting layer, and a second electrode;
a bank on the first electrode, and defining the emission area where the first electrode is exposed, and defining the non-emission area where the bank is located;
a taper pattern on the substrate and interposed between the circuit element and the bank at the non-emission area,
wherein the bank includes an incline extending from an edge of the emission area to a predetermined distance into the non-emission area, the incline of the bank defining a taper area, and
wherein the taper pattern is adjacent to or overlaps the taper area.

2. The display device of claim 1, wherein the incline of the bank has a predetermined angle relative to the substrate.

3. The display device of claim 1, wherein the taper pattern encircles the emission area.

4. The display device of claim 3, wherein the emission area is circular in shape, and the taper pattern is annular in shape.

5. The display device of claim 3, wherein the taper pattern includes a plurality of segments that encircle the emission area.

6. The display device of claim 1, wherein the circuit element includes a source electrode and a drain electrode, and
wherein the taper pattern includes a same material as the source electrode or the drain electrode.

7. The display device of claim 1, further comprising a taping spacer on the incline of the bank, and having a different slope from a slope of the incline of the bank.

8. The display device of claim 7, wherein the different slope of the taping spacer is greater than the slope of the incline of the bank.

9. The display device of claim 1, wherein the taper pattern overlaps the first electrode.

10. The display device of claim 1, wherein the taper pattern overlaps the taper area.

11. The display device of claim 1, further comprising a spacer on the bank and in the non-emission area.

12. The display device of claim 11, wherein the spacer has a shape that includes at least one of a dot, a circle, an oval, a polygon, a line and a curve.

13. The display device of claim 1, further comprising a taping spacer that is located in the non-emission area and overlapping the taper area.

14. The display device of claim 13, wherein the taping spacer has a first portion adjacent to the emission area and a second portion opposite to the non-emission area, and
wherein a slope of the first portion is larger than a slope of the second portion.

15. The display device of claim 14, wherein the first portion and the second portion are portions of a curved surface of the taping spacer.

16. The display device of claim 1, wherein the bank is formed of a black material.

17. The display device of claim 1, wherein the taper pattern is formed on a same layer as a source-drain electrode connected to a source electrode or a drain electrode constituting the circuit element.

18. A display device comprising:
a substrate including an emission area and a non-emission area;
a circuit element on the substrate;
a light emitting element electrically connected to the circuit element and including a first electrode, a light emitting layer, and a second electrode;
a bank on the first electrode, and defining the emission area where the first electrode is exposed, and defining the non-emission area where the bank is located; and
a taping spacer on the bank,
wherein the bank includes an incline extending from an edge of the emission area to a predetermined distance into the non-emission area, the incline of the bank defining a taper area, and
wherein the taping spacer is on the taper area of the bank and has a different slope from a slope of the incline of the bank.

19. The display device of claim 18, wherein the bank is formed of a black material.

20. The display device of claim 19, further comprising a spacer on the bank and in the non-emission area, and
wherein the spacer has a shape that includes at least one of a dot, a circle, an oval, a polygon, a line and a curve.
